(19) United States
(12) Patent Application Publication
(10) Pub. No.: US 2004/0062020 A1
(43) Pub. Date: Apr. 1, 2004

(54) EMI shield for an integrated circuit

(76) Inventors: Winnie C. Leung, Mountain View, CA (US); Russell K. Brovald, Mountain View, CA (US); David M. Hockanson, Boulder Creek, CA (US); Anthony R. Fredriksson, Mountain View, CA (US); Mason Mok, San Jose, CA (US)

Correspondence Address: BLAKELY, SOKOLOFF, TAYLOR & ZAFMAN LLP, Seventh Floor, 12400 Wilshire Boulevard, Los Angeles, CA, 90025-1030, US

(21) Appl. No.: 10/212,966

(22) Filed: Aug. 5, 2002

(51) Int. Cl. H05K 9/00

(52) U.S. Cl. 361/816

(57) ABSTRACT

According to one embodiment, a circuit board is disclosed. The circuit board includes a grounding ring, an integrated circuit, a heat spreader mounted on the integrated circuit and an electromagnetic shield. The electromagnetic shield is mounted on the grounding ring around the integrated circuit to electrically ground the heat spreader to the circuit board in order to trap electromagnetic interference generated by the integrated circuit.

### FIELD OF THE INVENTION

The present invention relates to integrated circuits; more particularly, the present invention relates to suppressing electromagnetic field interference (EMI) generated by integrated circuits.

### BACKGROUND

With the rapid development of technology, the speed of central processing units (CPUs) within computer systems has increased. However, the increased speed of CPUs increases the level of electromagnetic field interference (EMI) that is generated.

Typical computer systems include a heat spreader and a heat sink clipped over a CPU to a motherboard for thermal management. EMI noise generated by the CPU may be coupled to the heat spreader and heat sink. The heat spreader and heat sink may radiate the noise causing interference in other components within the computer system.

Some computer systems implement an EMI shield in order to ground the heat spreader and heat sink to the motherboard. Often, such EMI shields do not provide a continuous ring around the CPU, thus, not sufficiently reducing the EMI noise generated by the CPU. Moreover, the current shield designs that implement a continuous ring around the CPU either require pins to be soldered to the motherboard or require tools for removal and/or replacement. Soldering the shield to the motherboard or requiring tools for removal and/or replacement precludes the easy servicing of the CPU when necessary.

### SUMMARY

According to one embodiment, a circuit board is disclosed. The circuit board includes a grounding ring, an integrated circuit, a heat spreader mounted on the integrated circuit and an electromagnetic shield. The electromagnetic shield is mounted on the grounding ring around the integrated circuit to electrically ground the heat spreader to the circuit board in order to trap electromagnetic interference generated by the integrated circuit.

In a further embodiment, the circuit board comprises a connector coupled to the integrated circuit and ground pins coupled to the connector to ground the integrated circuit. In addition, the circuit board includes a ground plane between the grounding ring and the ground pins that couples the grounding ring to the ground pins. In yet another embodiment, the circuit board includes a heat sink coupled to the heat spreader and the shield. The shield also grounds the heat sink to the circuit board in order to trap electromagnetic interference generated by the integrated circuit.

### DESCRIPTION OF THE DRAWINGS

The present invention will be understood more fully from the detailed description given below and from the accompanying drawings of various embodiments of the invention. The drawings, however, should not be taken to limit the invention to the specific embodiments, but are for explanation and understanding only.

FIG. 1 illustrates one embodiment of a motherboard;

FIG. 2 illustrates one embodiment of a motherboard with an integrated circuit;

FIG. 3 illustrates one embodiment of an electromagnetic shield for an integrated circuit; and

FIG. 4 illustrates one embodiment of an electromagnetic shield with a heat sink and cooling fan.

### DETAILED DESCRIPTION

An electromagnetic field interference (EMI) shield for a central processing unit (CPU) and heat sink is described. In the following description, numerous details are set forth. It will be apparent, however, to one skilled in the art, that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

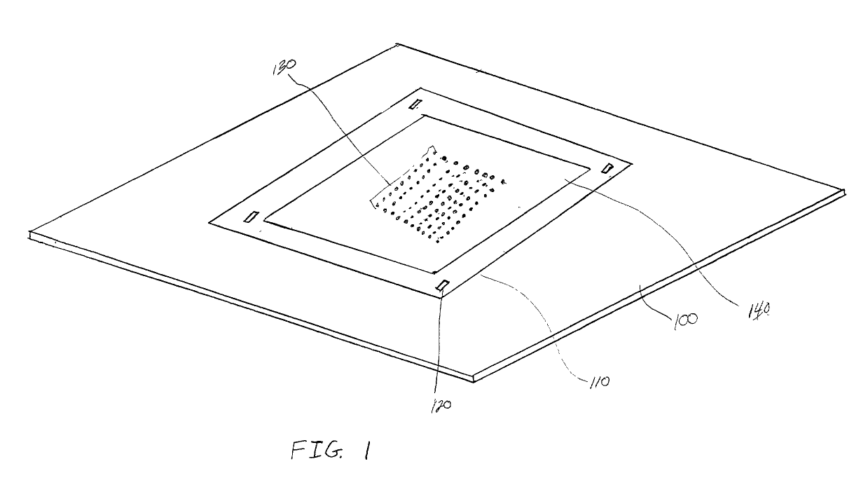

FIG. 1 illustrates one embodiment of a motherboard 100. Motherboard 100 is a physical arrangement in a computer system that includes the computer system's basic circuitry and components. On motherboard 100, circuitry is imprinted or affixed to the surface of a firm planar surface. According to one embodiment, motherboard 100 includes a grounding ring 110, alignment slots 120, ground pins 130 and a ground plane 140.

Grounding ring 110 provides an electrical ground for an electromagnetic interference (EMI) shield (not shown) that may be mounted on motherboard 100. Alignment slots 120 are used to couple the EMI shield to motherboard 100. The EMI shield includes prongs that slip into alignment slots 120 for the proper attachment and alignment.

Ground pins 130 provide an electrical ground for an integrated circuit (not shown) that may be mounted on motherboard 100. Ground pins 130 are coupled to a ground at a lower level of motherboard 100. On exemplary motherboards, a ground ring (e.g., grounding ring 110) is also coupled directly to a lower ground layer using blind vias.

However, according to one embodiment, grounding ring 110 is grounded to ground pins 130 by ground plane 140. Ground plane 140 is covered with a solder mask that insulates ground plane 140. In one embodiment, ground plane 140 ties into ground pins 130 in order to connect to the ground layer. In such an embodiment, ground plane 140 is flooded with conductive material around ground pins 130 on the top layer of motherboard 100. As a result, no separate wires or vias are necessary to couple grounding ring 110 to the ground layer.

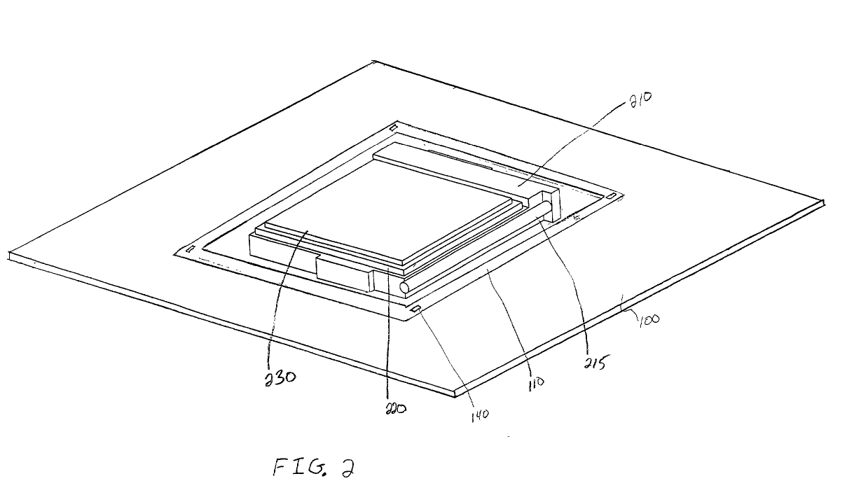

FIG. 2 illustrates another embodiment of motherboard 100. In this embodiment, motherboard 100 includes connector 210, lever 215, integrated circuit (IC) 220, and heat spreader 230. Connector 210 is mounted on motherboard 100 within grounding ring 110. In addition, connector 210 is mounted on ground pins 130.

Connector 210 facilitates an electrical connection between IC 220 and circuits on motherboard 100. According to one embodiment, connector 210 is a zero insertion force (ZIF) connector. Lever 215 is used to lock and unlock IC 220 into connector 210. Thus, IC 220 may be easily removed and inserted for servicing. Typically, an IC 220 may be installed into connector 210 by inserting the IC 210 into connector 210 and pulling down lever 215 to lock the IC 220 pins into connector 210. To remove IC 220, lever 215 is lifted up to unlock the pins.

IC 220 is a semiconductor wafer on which thousands or millions of tiny resistors, capacitors, and transistors are fabricated. According to one embodiment, IC 220 is a microprocessor. However, in other embodiments, IC 210 may function as an amplifier, oscillator, timer, counter, memory, or other circuitry.

Heat spreader 230 protects IC 220 and helps diffuse the heat generated by IC 220. In particular, heat spreader 230 distributes heat generated from one concentrated source of IC 220 across a larger surface area. According to one embodiment, heat spreader 230 is an aluminum sheath covering IC 220. However, heat spreader 230 may be implemented using other heat conductive materials.

The die of a high-speed IC typically generates EMI noise in proportion to the operation speed. Thus, as the noise increases it couples to heat spreader 230 above IC 220. If heat spreader 230 is not well grounded, an electromagnetic field couples to other components on motherboard 100 or within the computer system.

Once the structures within the computer system have noise induced on them they function as antenna and re-radiate the noise. Therefore, a mechanism is needed to capture generated electromagnetic fields and return the fields to ground on motherboard 100 as close as possible to the original source of the noise (e.g., IC 220).

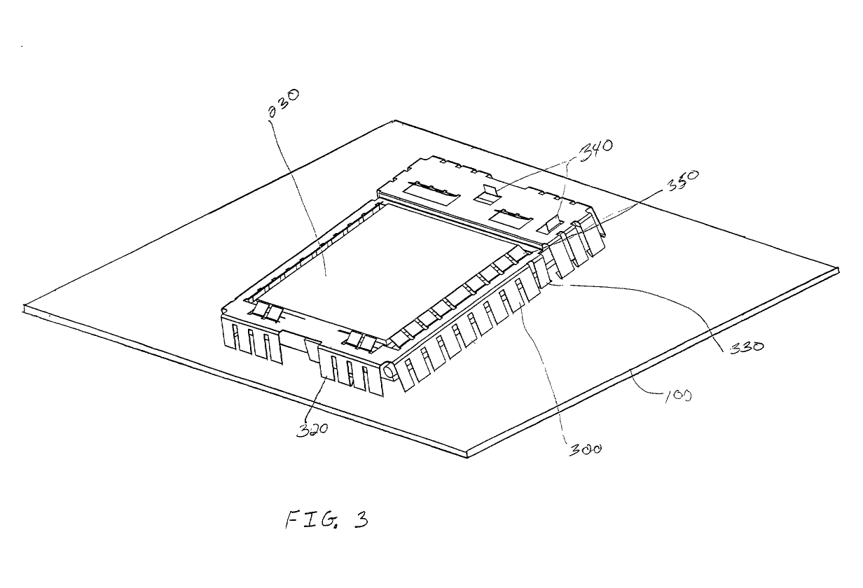

FIG. 3 illustrates one embodiment of an EMI shield 300. Shield 300 is mounted on grounding ring 110 around connector 210, lever 215, IC 220, and heat spreader 230. Shield 300 reduces electromagnetic field loops, and traps EMI noise by grounding heat spreader 230 to motherboard 100. In particular, shield 300 returns EMI noise through its walls to grounding ring 110, which is closely coupled to the return path.

In one embodiment, shield 300 may be easily removed without the use of tools to facilitate the servicing of IC 220. In another embodiment, shield 300 is constructed of stainless steel. However, one of ordinary skill in the art will appreciate that shield 300 may be constructed with other materials.

EMI shield 300 includes springs 320 and 340, alignment prongs 330 and thermal connectors 350. Springs 320 and/or the opening in the top of shield 300 through which heat spreader 230 may protrude are used to align EMI shield 300 with connector 210, heat spreader 230 and grounding ring 110. It will be apparent, however, to one of ordinary skill in the art that springs 320 and 340 may be integrally formed from the shield 300 material, or may be separately attached to shield 300 and formed of another material such as conductive foam or conductive fabric over foam or any other material that is that is electrically conductive and provides suitable spring like properties.

Alignment prongs 330 slide into alignment slots 120 to ensure that shield 300 maintains proper contact and alignment with grounding ring 110. In one embodiment, heat spreader 230 is also used as an alignment mechanism for shield 300. Springs 340 assist in aligning a heat sink that may be mounted on heat spreader 230 to further dissipate heat generated by IC 220. Thermal connectors 350 couple with a heat sink to ground any EMI noise passed on from heat spreader 230 to the heat sink.

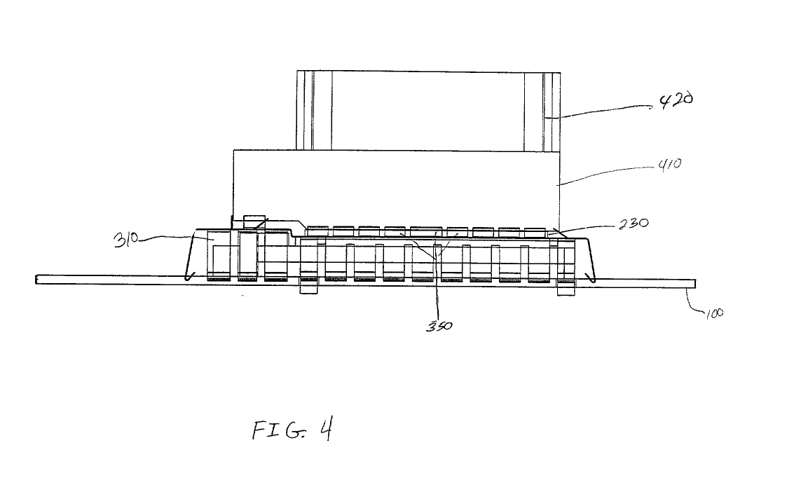

FIG. 4 illustrates another embodiment of EMI shield 300. In this embodiment, a heat sink 410 is mounted on heat spreader 230 and shield 300 using springs 340 and connectors 350. Heat sink 410 is attached to heat spreader 230 to prevent IC 220 from overheating. Heat sink 410 absorbs the heat and dissipates it into the air. To ensure that the heat sink can absorb as much heat as possible, a thermal lubricant may be used to create a seal between heat sink 410 and heat spreader 230.

A cooling fan 420 is mounted on heat sink 410 to further dissipate thermal energy generated by IC 220 by blowing air across heat sink 410. In one embodiment, heat sink 410 is an active heat sink that includes fan 420 (e.g., called a heat sink/fan combo (HSF)). However, in other embodiments, heat sink 420 may be a passive heat sink that comes without fan 420.

As described above, shield 300 may be easily removed without the use of tools to facilitate the servicing of IC 220. For instance, whenever heat sink 410 is clipped to motherboard 100 the spring fingers 320 and 340 of shield 300 are compressed, thus securing shield 300.

EMI shield 300 reduces electromagnetic field loops and traps EMI noise by grounding heat spreader 230 and heat sink 410 to motherboard 100 via grounding ring 110. Grounding ring 110 is connected to a ground layer in motherboard 100 via ground plane 140 coupled to ground pins 130. Thus, EMI shield 300 captures EMI noise and returns the noise to ground on motherboard 100 near IC 220.

In addition, shield 300 may be easily removed to facilitate the servicing of IC 220. Moreover, using the motherboard 100 top layer ground plane to electrically connect grounding ring 110 to any other ground layers of motherboard 100 through IC 220 and/or connector 210 ground pins obviates the necessity of using expensive blind via construction to create the grounding ring.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims which in themselves recite only those features regarded as the invention.

What is claimed is:

1. A circuit board comprising:
a grounding ring;
an integrated circuit;
a heat dissipation device mounted on the integrated circuit; and
an electromagnetic shield mounted on the grounding ring around the integrated circuit.

2. The circuit board of claim 1 wherein the shield electrically grounds the heat dissipation device to the circuit board in order to trap electromagnetic interference generated by the integrated circuit.

3. The circuit board of claim 2 wherein the shield reduces electromagnetic field loops generated by the integrated circuit.

4. The circuit board of claim 1 further comprising one or more alignment slots located in the ground ring to mount the shield.

5. The circuit board of claim 4 further comprising:
a connector coupled to the integrated circuit; and
ground pins, coupled to the connector, to ground the integrated circuit.

6. The circuit board of claim 1 further comprising a ground plane between the grounding ring and the ground pins that couples the grounding ring to the ground pins.

7. The circuit board of claim 4 further comprising a heat sink coupled to the heat dissipation device and the shield, wherein the shield grounds the heat sink to the circuit board in order to trap electromagnetic interference generated by the integrated circuit.

8. The circuit board of claim 7 further comprising a cooling fan mounted on the to the heat sink.

9. The circuit board of claim 1 wherein the integrated circuit is a central processing unit (CPU).

10. The circuit board of claim 5 wherein the shield comprises:
a first set of springs to align the shield with the connector and the heat dissipation device; and
alignment prongs couple with the alignment slots to mount the shield into the grounding ring

11. The circuit board of claim 10 wherein the shield comprises a second set of springs to align the shield with a heat sink.

12. The circuit board of claim 11 wherein the heat dissipation device operates as an alignment mechanism for the shield.

13. The circuit board of claim 10 wherein the shield comprises one or more thermal connectors to couple the shield with the heat sink to ground electromagnetic interference noise passed from the heat dissipation device to the heat sink

14. The circuit board of claim 1 wherein the circuit board is a motherboard

15. A circuit board comprising:
a plurality of ground pins that are electrically grounded by a ground layer of the circuit board;
a ground plane that couples to the ground layer via the ground pins;
a grounding ring coupled to the ground plane;
an integrated circuit mounted on the ground pins;
a heat spreader mounted on the integrated circuit; and
an electromagnetic shield, mounted on the grounding ring around the integrated circuit, to trap electromagnetic interference generated by the integrated circuit.

16. The circuit board of claim 15 wherein the ground plane is flooded with an electrically conductive material around the ground pins.

17. The circuit board of claim 15 further comprising a connector coupled between the grounding pins and the integrated circuit.

18. The circuit board of claim 15 further comprising a heat dissipation device mounted on the integrated circuit.

19. The circuit board of claim 18 wherein the heat dissipation device operates as an alignment mechanism for the shield.

20. The circuit board of claim 19 wherein the shield comprises:
a first set of springs to align the shield with the connector and the heat dissipation device; and
alignment prongs couple with the alignment slots to mount the shield into the grounding ring

21. The circuit board of claim 20 wherein the shield comprises a second set of springs to align the shield with a heat sink.

22. The circuit board of claim 18 further comprising a heat sink coupled to the heat dissipation device and the shield, wherein the shield grounds the heat sink to the circuit board in order to trap electromagnetic interference generated by the integrated circuit.

23. A circuit board comprising:
a connector mounted on the circuit board;
an integrated circuit mounted on the connector;
a heat spreader mounted on the integrated circuit;
an electromagnetic shield, mounted on the circuit board around the integrated circuit, the shield including:
a first set of springs to align the shield with the connector;
alignment prongs couple with the alignment slots to mount the shield into the grounding ring; and
a second set of springs; and
a heat sink, mounted on the heat spreader to secure the shield to the circuit board by compressing the second set of springs and causing the compression of the first set of springs.

24. The circuit board of claim 23 wherein the heat dissipation device operates as an alignment mechanism for the shield.

25. The circuit board of claim 23 further comprising a cooling fan mounted on the heat sink.

26. The circuit board of claim 23 wherein the integrated circuit is a central processing unit (CPU).

27. The circuit board of claim 23 wherein the circuit board is a motherboard.
